(19) United States
(12) Patent Application Publication
(10) Pub. No.: US 2026/0360441 A1
(43) Pub. Date: Nov. 12, 2026

(54) METHODS AND SYSTEMS TO COMPENSATE FOR BIT LINE TO BIT LINE INTERFERENCE

(71) Applicant: Micron Technology, Inc., Boise, ID (US)

(72) Inventors: Massimo Ernesto Bertuccio, Milan (IT); Alessio Urbani, Rome (IT); Enrico Vicini, Pescantina (IT)

(73) Assignee: Micron Technology, Inc., Boise, ID (US)

(21) Appl. No.: 19/654,031

(22) Filed: Apr. 21, 2026

Related U.S. Application Data
(60) Provisional application No. 63/802,468, filed on May 8, 2025.

(51) Int. Cl. G11C 16/24; G11C 16/04; G11C 16/08; G11C 16/26

(52) U.S. Cl. CPC G11C 16/24; G11C 16/0483; G11C 16/08; G11C 16/26

(57) ABSTRACT

Methods, systems, and devices for techniques to compensate for bit line to bit line interference. A memory device includes memory cells, and control logic coupled to the memory cells. The control logic receives first and second read values corresponding to a page of the memory cells. The control logic identifies a changed memory cell of the page of the memory cells. The changed memory cell includes a memory cell for which a corresponding first read value is different than a corresponding second read value. The control logic determines a level of aggression for a bit line coupled to the changed memory cell based on at least two of the read values corresponding to memory cells coupled to neighboring bit lines. The control logic selects a read value associated with the changed memory cell as an actual read value for the changed memory cell based on the corresponding level of aggression.

### CROSS-REFERENCE TO RELATED APPLICATION

This patent application claims the benefit of and priority to U.S. Provisional App. No. 63/802,468 filed May 8, 2025 titled “METHODS AND SYSTEMS TO COMPENSATE FOR BIT LINE TO BIT LINE INTERFERENCE,” which is incorporated in the present disclosure by reference in its entirety.

### TECHNICAL FIELD

This disclosure relates to one or more systems for memory, including techniques for compensating for bit line to bit line (BL-BL) interference.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells. Information can also be erased from the memory cells and new information can be stored in the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not- or (NOR) and not- and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 is a block diagram of a memory device in communication with a memory system controller of a memory system, in accordance with examples as disclosed herein.

FIGS. 2A-2C are illustrative schematics of portions of an array of memory cells in a memory device, in accordance with examples as disclosed herein.

FIG. 2D illustrates an example of a memory device including multiple blocks of memory cells in accordance with examples as disclosed herein.

FIG. 3 is a block diagram of an example apparatus for implementing one or more systems and for performing one or more methods described herein, in accordance with examples as disclosed herein.

FIGS. 4A and 4B illustrate an example three-dimensional structure of a memory device in accordance with examples as disclosed herein.

FIG. 5 illustrates a graphical representation of an example heat map of read values obtained as part of a read operation performed on a page of memory cells.

FIG. 6 illustrates a block diagram of an example sense circuit and string of memory cells.

FIG. 7 illustrates a graphical representation of voltage measured on an example sense node.

FIG. 8 illustrates a graphical representation of an example current vs voltage (IV) curve.

FIG. 9 illustrates a flowchart showing a method that supports techniques for compensating for BL-BL interference in accordance with examples as disclosed herein.

### DETAILED DESCRIPTION

The memory cells of a memory device may be arranged in rows and columns that are coupled to corresponding word lines and bit lines. Each of the rows of memory cells correspond to a different word line and each of the columns of the memory cells correspond to a different bit line. The memory device biases the word lines and the bit lines to different levels to perform read operations of the memory cells (e.g., read information stored in the memory cells) in accordance with an appropriate reading scheme.

One example reading scheme includes three boost modulation. During three boost modulation, the memory device applies boost voltages to sense nodes that correspond to different columns of the memory cells after corresponding sense phases of a read operation. The boost voltages may cause voltage levels of the sense nodes to change in multiple steps. During each step, the memory device compares the voltage levels of the sense nodes to corresponding voltage threshold (Vt) values to determine to which of the supported states a corresponding memory cell is programmed to. Three boost modulation may allow the memory device to determine three read values during a single sense phase of the read operation to reduce an amount of time used to perform the read operation.

Some memory devices include an “active architecture” in which the bit lines are not shielded from other bit lines (e.g., includes unshielded bit lines). For example, these memory devices may not implement “shielding bit lines,” which include inactive bit lines (e.g., bit lines not associated with memory cells that are being read) being positioned between active bit lines (e.g., bit lines that are associated with memory cells that are being read). The lack of shielding may permit capacitive coupling or cross talk to occur between the bit lines (e.g., BL-BL interference) during the read operation.

The BL-BL interference can cause the read values to include errors, which may introduce errors into the data that is being read out. Additionally or alternatively, the BL-BL interference can impact overall performance of the read operations of the memory device. For example, the BL-BL interference can specifically limit a lower bound of bit line settling time (e.g., a read rate of the memory device) when an equal read window budget (RWB) is applied.

The present disclosure provides techniques for avoiding or reducing the technical difficulties described above. Some embodiments described in the present disclosure include a memory device that determines multiple read values for each of the memory cells that is being read in a page and selects an actual read value for these memory cells based on changes in the determined read values and levels of aggression of BL-BL interference (generally referred to in the present disclosure as “levels of aggression” or “level of aggression”).

The memory device (e.g., by using a controller) determines the read values for the memory cells that are being read in the page (generally referred to in the present disclosure as “the read memory cells”) by comparing voltage levels within the memory device to corresponding reference voltages at different points in time. For example, the memory device can determine the read values by comparing voltage levels of the sense nodes at different points in time (e.g., adjusting bias voltages or performing multiple sense phases) to the Vt values of a corresponding transistor to set the read values to a logical 1 or a logical 0.

The memory device identifies changed memory cells (e.g., the read memory cells for which read values are different at different points in time). In addition, the memory device determines the levels of aggression for the bit lines coupled to the changed memory cells (generally referred to in the present disclosure as the neighboring bit lines). The memory device may determine the levels of aggression for the bit lines coupled to the changed memory cells based on the read values that correspond to memory cells coupled to the neighboring bit lines. Further, the memory device, for each of the changed memory cells, selects a corresponding read value as an actual read value based on the corresponding level of aggression. These and other embodiments are described in more detail below.

The memory device described in the present disclosure can improve performance of a read operation performed by the memory device. For example, the memory device described in the present disclosure may improve performance and/or accuracy of the read operation in scaled technologies. As another example, the memory devices described in the present disclosure may increase an accuracy of the read operation and the data being read out.

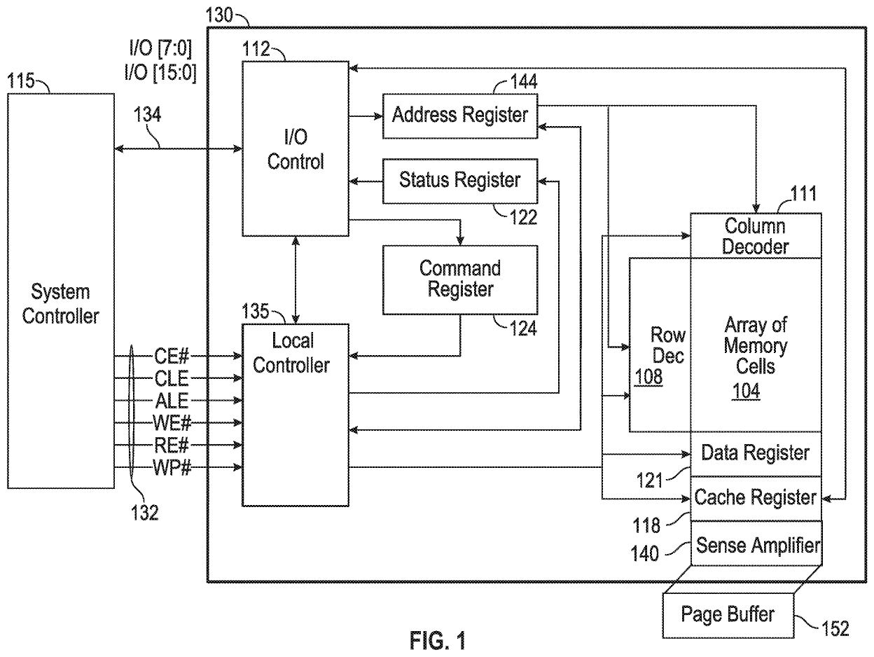

FIG. 1 is a simplified block diagram of a memory device 130 in communication with a system controller 115 of a memory system according to an embodiment. A memory system may be or include any device or collection of devices, where the device or collection of devices includes at least one memory array. For example, a memory system may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices. A memory system may communicate with a host system, which may include a host system controller. The host system may be implemented using one or more processors and a memory system for writing data to the memory system, reading data from the memory system, erasing data, or refreshing data.

A memory system may include one or more memory devices, such as device 130. A memory device 130 may include one or more memory arrays of any type of memory cells (e.g., non-volatile memory cells, volatile memory cells, or any combination thereof). For example, memory device 130 may include NAND (e.g., NAND flash) memory, ROM, phase change memory (PCM), NOR (e.g., NOR flash) memory, etc. In some cases, memory device 130 is a NAND memory device 130, which may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

As shown in FIG. 1 and described below in more detail, memory device 130 includes an array of memory cells 104 logically arranged in rows and columns. Memory cells of a logical row are typically connected to the same access line (e.g., a word line) while memory cells of a logical column are typically selectively connected to the same data line (e.g., a bit line). A single access line can be associated with more than one logical row of memory cells and a single data line can be associated with more than one logical column. Memory cells (not shown in FIG. 1) of at least a portion of the array of memory cells 104 are capable of being programmed to one of at least two target data states for storing any number of bits of information.

With continued reference to FIG. 1, row decode circuitry 108 and column decode circuitry 111 are provided to decode address signals. Address signals are received and decoded to access the array of memory cells 104. Memory device 130 also includes input/output (I/O) control circuitry 112 to manage input of commands, addresses, and data to memory device 130 as well as output of data and status information from memory device 130. An address register 144 is in communication with I/O control circuitry 112 and row decode circuitry 108 and column decode circuitry 111 to latch the address signals prior to decoding. The row decode circuitry 108 and the column decode circuitry 111 may simply be referred to as a row decoder 108 and a column decoder 111, respectively. A command register 124 is in communication with the I/O control circuitry 112 and a local controller 135 to latch incoming commands.

A memory controller (e.g., the local controller 135 internal to memory device 130) controls access to the array of memory cells 104 in response to the commands and generates status information for the external system controller 115, i.e., the local controller 135 is configured to perform access operations (e.g., read operations, program operations, and/or erase operations) on the array of memory cells 104. The local controller 135 is in communication with row decode circuitry 108 and the column decode circuitry 111 to control the row decode circuitry 108 and the column decode circuitry 111 according to the addresses.

In some embodiments, the local controller 135 communicates with the external system controller 115, which may be a host controller (e.g., an UFS or eMMC controller, or a CPU communicating with the local controller 135) located in a host system or a memory system controller located in a memory system. In some embodiments, local controller 135 is disposed on the same semiconductor die as the memory array (e.g., array of memory cells 104), and a separate system controller 115 is disposed on a different die. In other examples, some portions of the memory device 130 may be disposed on a first die and other portions of the memory device 130 may be disposed on a second die different from the first die. For instance, the first die may include the array of memory cells 104 and its associated circuitry such as the column decoder 111 and row decoder 108, etc. The second die may include logic circuitry, power circuitry, or other circuitry of the memory device 130. Thus, the second die may include the system controller 115, the I/O control circuitry 112, etc. In this example, the first die has no local controller, and the second die includes the system controller 115. The first die and the second die can be hybrid bonded together using, for example, through-hole vias (TSVs) such that they are electrically connected. The first die and the second die may also be wafer-bonded using flip-chip bonding technologies, etc. In this disclosure, the system controller 115 and the local controller 135 may both be referred to as memory controllers, or a first memory controller and a second memory controller, for simplicity. It is understood that while they may be different controllers, certain operations disclosed herein may be caused or performed by either or both memory controllers, unless otherwise specified.

The local controller 135 is also in communication with a cache register 118, a data register 121, and a sense amplifier 140. In some embodiments, one or more cache registers 118 can collectively form at least a part of a cache buffer. The cache register 118 latches or buffers data, either incoming or outgoing, as directed by the local controller 135 to temporarily store data while the array of memory cells 104 is busy writing or reading, respectively, other data. During a program operation (e.g., write operation), data can be passed from the cache register 118 to the data register 121 for transfer to the array of memory cells 104; then new data can be latched in cache register 118 from the I/O control circuitry 112. During a read operation, data can be passed from the cache register 118 to the I/O control circuitry 112 for output to the system controller 115; then new data can be passed from the data register 121 to the cache register 118. In some embodiments, the cache register 118 and/or the data register 121 can form at least a portion of a page buffer 152 of the memory device 130. The sense amplifier 140 may be configured to sense a data state of a memory cell of the array of memory cells 104, e.g., by sensing a state of a data line connected to that memory cell. A status register 122 can be in communication with the I/O control circuitry 112 and the local controller 135 to latch the status information for output to the system controller 115.

As shown in FIG. 1, the memory device 130 receives various control signals via the local controller 135 from the system controller 115 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) can be further received over the control link 132 depending upon the nature of the memory device 130. In one embodiment, the memory device 130 receives command signals (which represent commands), address signals (which represent addresses), and data signals (which represent data) from the system controller 115 over a multiplexed input/output (I/O) bus 134 and outputs data to the system controller 115 over the I/O bus 134.

For example, the commands can be received over input/output (I/O) pins [7:0] of the I/O bus 134 at the I/O control circuitry 112 and can then be written into a command register 124. The addresses can be received over input/output (I/O) pins [7:0] of the I/O bus 134 at I/O control circuitry 112 and can then be written into the address register 144. The data can be received over input/output (I/O) pins [7:0] for an 8-bit device or input/output (I/O) pins [15:0] for a 16-bit device at the I/O control circuitry 112 and then can be written into the cache register 118. The data can be subsequently written into the data register 121 for programming the array of memory cells 104.

In an embodiment, the cache register 118 can be omitted, and the data can be written directly into the data register 121. Data can also be output over input/output (I/O) pins [7:0] for an 8-bit device or input/output (I/O) pins [15:0] for a 16-bit device. Although reference can be made to I/O pins, they can include any conductive node providing for electrical connection to the memory device 130 by an external device (e.g., the system controller 115), such as conductive pads or conductive bumps as are commonly used. While the above description uses 16 bits I/O bus 134 as an example, it is understood that the bus 134 can be configured to any number of bits (e.g., 64 bits).

It will be appreciated by those skilled in the art that additional circuitry and signals can be provided, and that memory device 130 of FIG. 1 has been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1. Additionally, while specific I/O pins are described in accordance with popular conventions for receipt and output of the various signals, it is noted that other combinations or numbers of I/O pins (or other I/O node structures) can be used in the various embodiments.

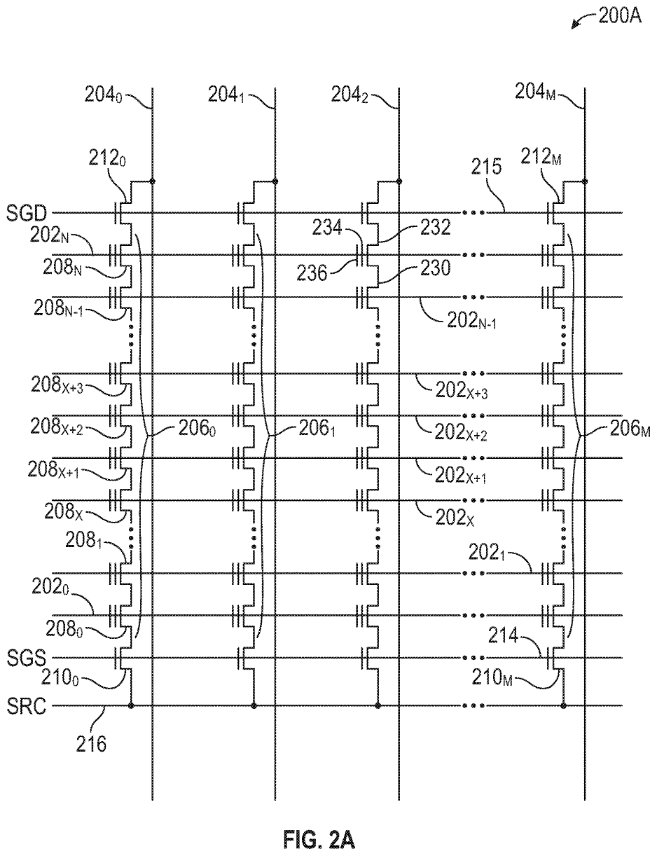

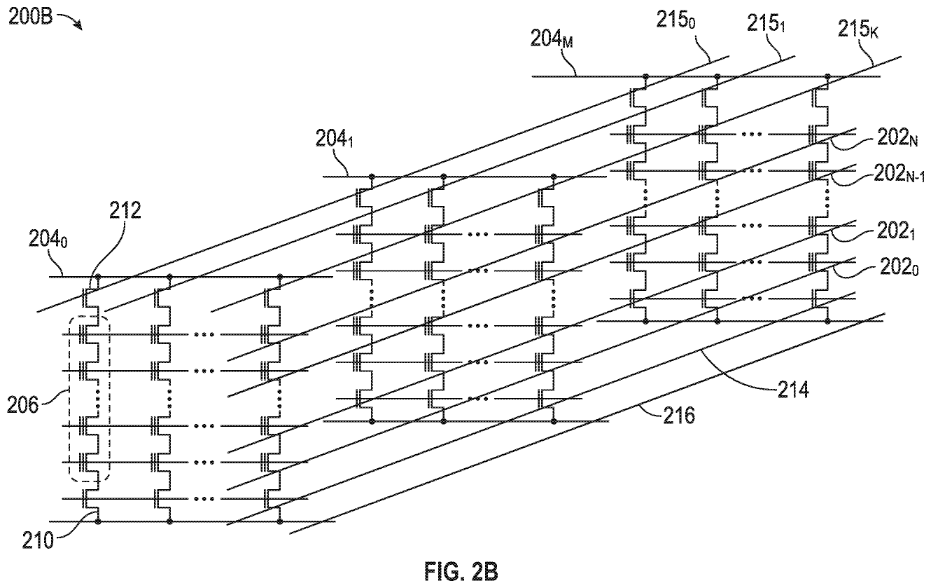

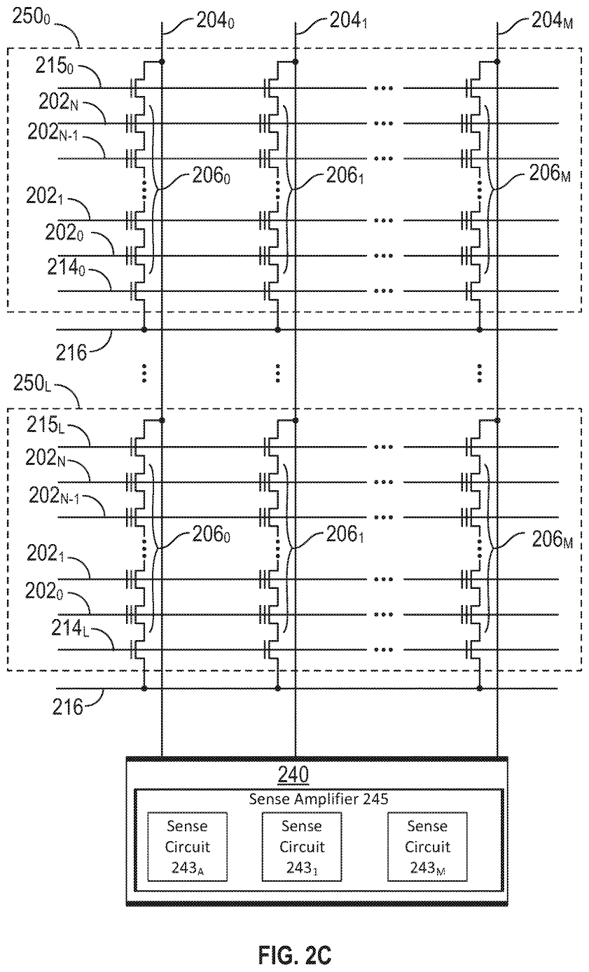

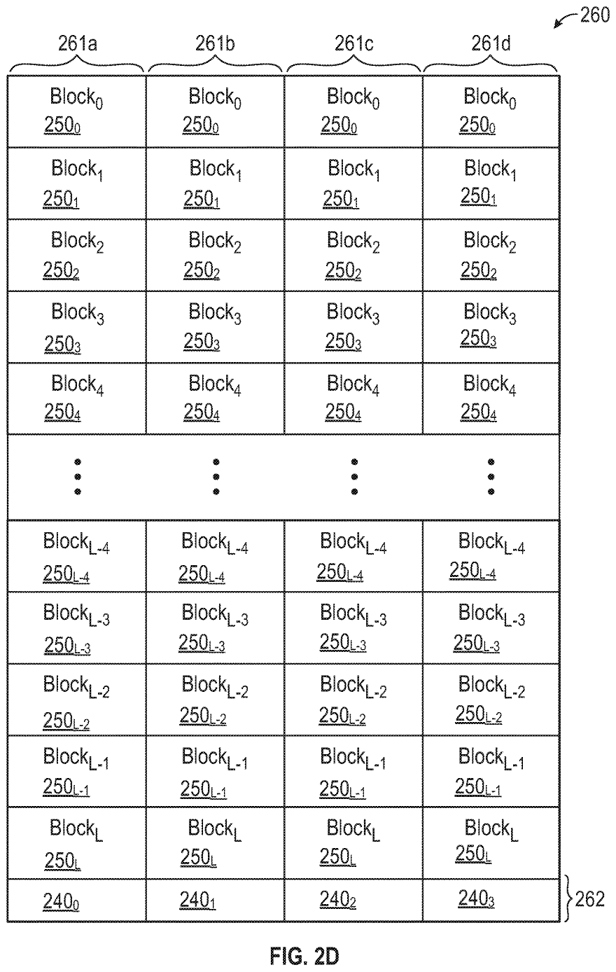

FIG. 2A-2B are example schematics of portions of an array of memory cells 200A, such as a NAND memory array. The array of memory cells 200A may be an example of the array of memory cells 104 of the memory device 130 as described with reference to FIG. 1 according to an embodiment. Memory array 200A includes access lines, such as word lines 202₀ to 202_{N}, and data lines, such as bit lines 2040 to 204M. The word lines 202 can be connected to global access lines (e.g., global word lines), not shown in FIG. 2A, in a many-to-one relationship. For some embodiments, memory array 200A can be formed over a semiconductor that, for example, can be doped to have a conductive type, such as a p-type conductivity, e.g., to form a p-well, or an n-type conductivity, e.g., to form an n-well.

Memory array 200A can be arranged in rows (each corresponding to a word line 202) and columns (each corresponding to a bit line 204). Each column can include a string of series-connected memory cells (e.g., non-volatile memory cells), such as one of NAND strings 2060 to 206M. Each NAND string 206 can be connected (e.g., selectively connected) to a common source (SRC) 216 and can include memory cells 2080 to 208N. The memory cells 208 can represent non-volatile memory cells for storage of data. The memory cells 208 of each NAND string 206 can be connected in series between a select transistor 210 (e.g., a field-effect transistor), such as one of the select gates 210₀ to 210_{M} (e.g., that can be source select transistors, commonly referred to as select gate source), and a select transistor 212 (e.g., a field-effect transistor), such as one of the select transistors 212₀ to 212_{M} (e.g., that can be drain select transistors, commonly referred to as select gate drain). The select gates 210₀ to 210_{M} can be commonly connected to a select line 214, such as a source select line (SGS), and the select gates 212₀ to 212_{M} can be commonly connected to a select line 215, such as a drain select line (SGD). Although depicted as traditional field-effect transistors, the select transistors 210 and 212 can utilize a structure similar to (e.g., the same as) the memory cells 208. The select transistors 210 and 212 can represent a number of select gates connected in series, with each select transistor in series configured to receive a same or independent control signal.

A source of each select transistor 210 can be connected to common source 216. The drain of each select transistor 210 can be connected to a memory cell 208₀ of the corresponding NAND string 206. For example, the drain of select gate 210₀ can be connected to memory cell 208₀ of the corresponding NAND string 206₀. Therefore, each select transistor 210 can be configured to selectively connect a corresponding NAND string 206 to the common source 216. A control gate of each select transistor 210 can be connected to select line 214.

The drain of each select transistor 212 can be connected to bit line 204 for the corresponding NAND string 206. For example, the drain of select gate 212₀ can be connected to the bit line 2040 for the corresponding NAND string 206₀. The source of each select transistor 212 can be connected to a memory cell 208_{N} of the corresponding NAND string 206. For example, the source of select gate 212₀ can be connected to memory cell 208_{N} of the corresponding NAND string 206₀. Therefore, each select transistor 212 can be configured to selectively connect a corresponding NAND string 206 to the corresponding bit line 204. A control gate of each select transistor 212 can be connected to select line 215.

The memory array 200A in FIG. 2A can be a quasi-two-dimensional memory array and can have a generally planar structure, e.g., where the common source 216, the NAND strings 206, and the bit lines 204 extend in substantially parallel planes. Alternatively, the memory array 200A in FIG. 2A can be a three-dimensional memory array, e.g., where the NAND strings 206 can extend substantially perpendicular to a plane containing the common source 216 and to a plane containing the bit lines 204 that can be substantially parallel to the plane containing the common source 216.

Typical construction of the memory cells 208 includes a data-storage structure 234 (e.g., charge trap and the like) that can determine a data state of the memory cell (e.g., through changes in threshold voltage), and a control gate 236, as shown in FIG. 2A. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a word line 202.

A column of the memory cells 208 can be a NAND string 206 or a number of NAND strings 206 selectively connected to a given bit line 204. A row of memory cells 208 can be memory cells 208 commonly connected to a given word line 202. A row of memory cells 208 can, but need not, include all the memory cells 208 commonly connected to a given word line 202. Rows of memory cells 208 can often be divided into one or more groups of physical pages of memory cells 208, and physical pages of the memory cells 208 often include every other memory cell 208 commonly connected to a given word line 202. For example, the memory cells 208 commonly connected to word line 202_{N} and selectively connected to even bit lines 204 (e.g., bit lines 2040, 2042, 2044, etc.) can be one physical page of the memory cells 208 (e.g., even memory cells) while memory cells 208 commonly connected to word line 202_{N} and selectively connected to odd bit lines 204 (e.g., bit lines 2041, 2043, 2045, etc.) can be another physical page of the memory cells 208 (e.g., odd memory cells).

Although the bit lines 2043-2045 are not explicitly depicted in FIG. 2A, it is apparent from the figure that the bit lines 204 of the array of memory cells 200A can be numbered consecutively from bit line 2040 to bit line 204M. Other groupings of memory cells 208 commonly connected to a given word line 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single program operation (e.g., an upper or lower page of memory cells) can be deemed a logical page of memory cells. A block of memory cells can include those memory cells that are configured to be erased together, such as all memory cells connected to word lines 202₀-202_{N} (e.g., all NAND strings 206 sharing common word lines 202). Unless expressly distinguished, a reference to a page of memory cells herein refers to the memory cells of a logical page of memory cells. A logical page may or may not be the same as a physical page. Although the example of FIG. 2A is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

FIG. 2B is another schematic of a portion of an array of memory cells 200B as could be used in a memory device 130, e.g., as a portion of the array of memory cells 104. Like numbered elements in FIG. 2B correspond to the description as provided with respect to FIG. 2A. FIG. 2B provides additional detail of one example of a three-dimensional NAND memory array structure. Three-dimensional NAND memory array 200B can incorporate vertical structures which can include semiconductor pillars where a portion of a pillar can act as a channel region of the memory cells of NAND strings 206. NAND strings 206 can be each selectively connected to a bit line 2040-204M by a select transistor 212 (e.g., that can be drain select transistors, commonly referred to as select gate drain) and to a common source 216 by a select transistor 210 (e.g., that can be source select transistors, commonly referred to as select gate source). Multiple NAND strings 206 can be selectively connected to the same bit line 204. Subsets of NAND strings 206 can be connected to their respective bit lines 204 by biasing the select lines 2150-215 to selectively activate particular select transistors 212 each between a NAND string 206 and a bit line 204. The select transistors 210 can be activated by biasing the select line 214. In some embodiments, each sub-block or string of memory cells has a separate select line 214 from other sub-blocks or strings. In some embodiments, a pair of sub-blocks shares a select line 214. Each word line 202 can be connected to multiple rows of memory cells of the memory array 200B. Rows of memory cells that are commonly connected to each other by a particular word line 202 can collectively be referred to as tiers.

The three-dimensional NAND memory array 200B may include multiple stacked layers of levels of memory cells and connected using vertical channels such as semiconductor pillars. The number of layers in three-dimensional NAND memory array 200B can be, for example, 32, 48, 64, 96, 112 layers, or any number of layers. In some examples, a group of layers may be collectively referred to as a deck. A deck in a three-dimensional NAND memory array may be processed together (e.g., etched together for forming a portion of the semiconductor pillar). A memory device having three-dimensional NAND memory arrays can provide more memory cells on a single chip than a memory device formed by two-dimensional NAND arrays; and therefore provide a higher storage capacity. Furthermore, in a memory device having three-dimensional NAND memory arrays, transistors in memory cells are spaced out, and therefore interference and electron leaks can be reduced.

In some examples, memory cells can be grouped into memory blocks. FIG. 2C depicts groupings of NAND strings 206 into blocks of memory cells 250, e.g., blocks of memory cells 2500-250L. Blocks of memory cells 250 can be groupings of memory cells 208 that can be erased together in a single erase operation. The group of memory cells that can be erased together is also referred to as an erase block. Each block of memory cells 250 can represent those NAND strings 206 commonly associated with a single select line 215, e.g., select line 2150. The common source 216 for the block of memory cells 2500 can be a same source as the source 216 for the block of memory cells 250L. For example, each block of memory cells 2500-250L can be commonly selectively connected to the source 216. Access lines 202 and select lines 214 and 215 of one block of memory cells 250 can have no direct connection to access lines 202 and select lines 214 and 215, respectively, of any other block of memory cells of the blocks of memory cells 2500-250L.

The bit lines 2040-204M can be connected (e.g., selectively connected) to a buffer portion 240, which can be a portion of the page buffer 152 of the memory device 130. The buffer portion 240 can correspond to a memory plane (e.g., the set of blocks of memory cells 2500-250L). The buffer portion 240 can include sense circuits (which can include sense amplifiers) for sensing data values indicated on respective bit lines 204. In addition, the buffer portion 240 may include a sense amplifier 245 that includes sense circuits 243₀-243_{M}. Each of the sense circuits 243₀-243_{M} may correspond to a different instance of the bit lines 204₀-204_{M}. For example, the sense circuit 243_{A} may correspond to the bit line 204_{A} and the sense circuit 243_{B} may correspond to the bit line 204_{B}. Each of the sense circuits 243₀-243_{M} may correspond to a different memory cell of the memory cells 208.

FIG. 2D is a block schematic of a portion of an example array of memory cells 260. Array of memory cells 260 can be used as the array of memory cells 104 in a memory device 130. The array of memory cells 260 is depicted as having four memory planes 261 (e.g., memory planes 261a-261d). Each of the memory planes 261 may refer to a group of memory blocks of memory cells 250. Each memory plane 261 can be in communication with a respective buffer portion 240, which can collectively form a page buffer 262. Page buffer 262 may be used to implement page buffer 152 shown in FIG. 1. While four memory planes 261 are depicted, other numbers of memory planes 261 can be commonly in communication with a page buffer 262. Each memory plane 261 is depicted to include L+1 blocks of memory cells 250 (e.g., blocks of memory cells 250₀-250_{L}).

In some cases, concurrent operations may be performed on different planes. For example, concurrent operations may be performed on memory cells within different blocks 250 so long as the different blocks 250 are in different planes 261. In some cases, an individual memory block 250 may be referred to as a physical block, and a virtual block may refer to a group of blocks 250 within which concurrent operations may occur. For example, concurrent operations may be performed on four blocks of 250₀ that are within planes 261a, 261b, 261c, and 261d, respectively, and the four blocks of 250₀ may be collectively referred to as a virtual block. In some cases, a virtual block may include blocks from different memory devices. In some cases, the physical blocks within a virtual block may have the same block address within their respective planes. In some cases, performing concurrent operations in different planes 261 may be subject to one or more restrictions, such as concurrent operations being performed on memory cells within different pages that have the same page address within their respective planes 261 (e.g., related to command decoding, page address decoding circuitry, or other circuitry being shared across planes 261).

In some cases, a block 250 may include memory cells organized into rows (pages) and columns (e.g., strings, not shown). For example, memory cells in a same page may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page may be the smallest unit of memory (e.g., set of memory cells) that may be independently programmed or read (e.g., programed or read concurrently as part of a single program or read operation), and a memory block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page may, in some cases, not be updated until the entire block that includes the page has been erased.

With continued reference to FIGS. 1 and 2A-2C, during a true erase operation (during which memory cells are actually being erased), the local controller 135 (e.g., using an erase operation manager 137) can cause a common source voltage line, e.g., the SRC 216 (FIG. 2A), to be ramped to an erase voltage (VERA) with an erase pulse while the select gates 210₀ to 210_{M} (SGS transistors) are turned on. Ramping to this high bias erase voltage, and the subsequent recovery from this voltage ramping, may take a significant amount of time. Concurrently, the erase operation manager 137 can cause the select gates 212₀ to 212ₘ (FIG. 2A) to be turned off to enable the drains of the select gates 212₀ to 212ₘ to float, which causes the bit lines 204₀ to 204_{M} to also float. Further, the erase operation manager 137 can couple the word lines 202 (FIG. 2A) to ground, e.g., zero volts, or retain the word lines 202 at a low voltage. This set of voltage levels at the memory array 200A can create an erase potential that causes the memory cells 2080 to 208_{N} to be erased, e.g., forces electrons to exit through a body of each memory cell and out the floating bit lines 204₀ to 204_{M}. In other embodiments, the reverse can be done so the select gates 210₀ to 210_{M} are turned off, causing the SRC line 216 to float while the voltage of the bit lines are ramped to Vera while the select gates 212₀ to 212_{M} are turned on. As mentioned earlier, in 3D NAND, one of the channel region, pillar, or bit line can also be ramped up in voltage to cause erasure of attached memory cells. In some embodiments, one or more sub-blocks, to include a physical block, of memory cells are erased during the same true erase operation. A block of memory cells can be generally understood to include four or more sub-blocks, wherein each sub-block includes a separate string of memory cells.

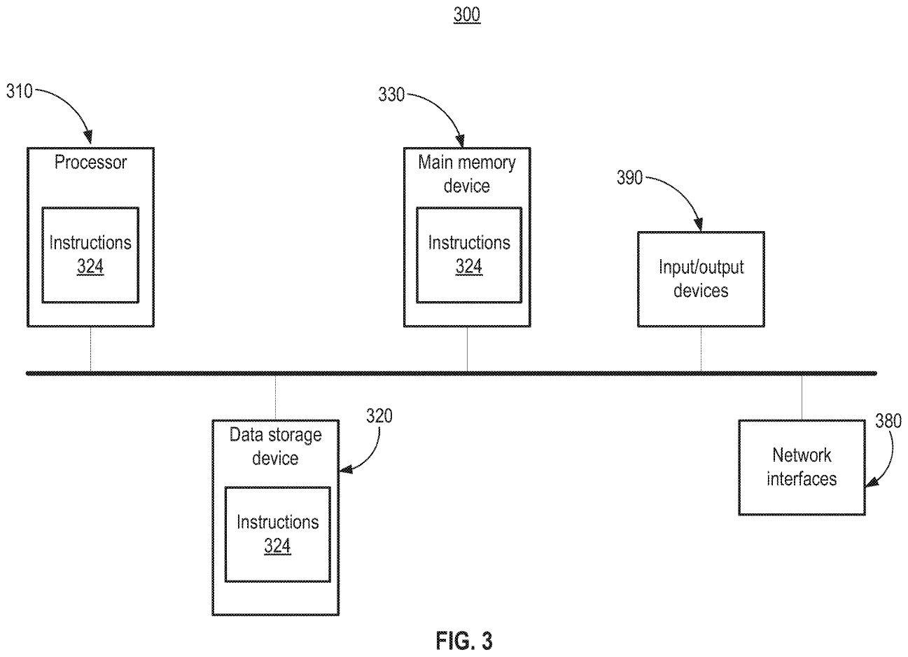

A high-level block diagram of an example apparatus 300 that may be used to implement systems, apparatus, and methods described herein is illustrated in FIG. 3. It is understood that various systems, apparatus, and methods described herein may be implemented using analog and/or digital circuitry, or using one or more computers using well-known computer processors, memory systems, storage devices, computer software, and other components. Typically, a computer includes a processor for executing instructions and one or more memory systems for storing instructions and data. A computer may also include, or be coupled to, one or more mass storage devices, such as one or more magnetic disks, internal hard disks and removable disks, magneto-optical disks, optical disks, etc.

Various systems, apparatus, and methods described herein may be implemented using computers operating in a client-server relationship. Typically, in such a system, the client computers are located remotely from the server computers and interact via a network. The client-server relationship may be defined and controlled by computer programs running on the respective client and server computers. Examples of client computers can include desktop computers, workstations, portable computers, cellular smartphones, tablets, or other types of computing devices.

Various systems, apparatus, and methods described herein may be implemented using a computer program product tangibly embodied in an information carrier, e.g., in a non-transitory machine-readable storage device, for execution by a programmable processor; and the method processes and steps described herein, including one or more of the steps of at least some of the FIGS. 1-9, may be implemented using one or more computer programs that are executable by such a processor. A computer program is a set of computer program instructions that can be used, directly or indirectly, in a computer to perform a certain activity or bring about a certain result. A computer program can be written in any form of programming language, including compiled or interpreted languages, and it can be deployed in any form, including as a stand-alone program or as a module, component, subroutine, or other unit suitable for use in a computing environment.

As shown in FIG. 3, apparatus 300 may be used to implement a host system that includes, is coupled to, or utilizes a memory system (e.g., memory system shown in FIG. 1). Apparatus 300 can be used to perform operations of a controller (e.g., to execute an operating system to perform operations corresponding to system controller 115 and/or local controller 135 of FIG. 1).

In some embodiments, apparatus 300 includes a processor 310 operatively coupled to a data storage device 320 and a main memory device 330. Processor 310 controls the overall operation of apparatus 300 by executing computer program instructions 324 that define such operations. The instructions 324 include instructions to implement functionality of a controller (e.g., system controller 115 and/or local controller 135 of FIG. 1). The computer program instructions 324 may be stored in data storage device 320, or other computer-readable medium, and loaded into main memory device 330 when execution of the computer program instructions is desired. For example, processor 310 may be used to implement one or more components and systems described herein, such as system controller 115 and/or local controller 135 (shown in FIG. 1). Thus, the method steps of at least some of FIGS. 1-9 can be defined by the computer program instructions 324 stored in main memory device 330 and/or data storage device 320 and controlled by processor 310 executing the computer program instructions 324. For example, the computer program instructions 324 can be implemented as computer executable code programmed by one skilled in the art to perform an algorithm defined by the method steps discussed herein in connection with at least some of FIGS. 1-9. Accordingly, by executing the computer program instructions, processor 310 executes an algorithm defined by the method steps of these aforementioned figures to perform operations (e.g., read, program, erase, etc.). Apparatus 300 also includes one or more network interfaces 380 for communicating with other devices via a network. Apparatus 300 may also include one or more input/output devices 390 that enable user interaction with apparatus 300 (e.g., display, keyboard, mouse, speakers, buttons, etc.).

Processor 310 may include both general and special purpose microprocessors and may be the sole processor or one of multiple processors of apparatus 300. Processor 310 may include one or more central processing units (CPUs), and one or more graphics processing units (GPUs), which, for example, may work separately from and/or multi-task with one or more CPUs to accelerate processing, e.g., for various image processing applications described herein. Processor 310, data storage device 320, and/or main memory device 330 may include, be supplemented by, or incorporated in, one or more application-specific integrated circuits (ASICs) and/or one or more field programmable gate arrays (FPGAs).

Data storage device 320 and main memory device 330 each include a tangible non-transitory computer readable storage medium. Data storage device 320, and main memory device 330, may each include high-speed random access memory, such as dynamic random access memory (DRAM), static random access memory (SRAM), double data rate synchronous dynamic random access memory (DDR RAM), or other random access solid state memory devices, and may include non-volatile memory, such as one or more magnetic disk storage devices such as internal hard disks and removable disks, magneto-optical disk storage devices, optical disk storage devices, flash memory devices (NAND memory devices, NOR memory devices), semiconductor memory devices, such as erasable programmable read-only memory (EPROM), electrically erasable programmable read-only memory (EEPROM), compact disc read-only memory (CD-ROM), digital versatile disc read-only memory (DVD-ROM) disks, or other non-volatile solid state storage devices. For example, data storage device 320 may be implemented using the memory system (e.g., system shown in FIG. 1) described herein. In some examples, data storage device 320 and main memory device 330 may include one or more memory devices 130 (FIG. 1).

Input/output devices 390 may include peripherals, such as a printer, scanner, display screen, etc. For example, input/output devices 390 may include a display device such as a cathode ray tube (CRT), plasma or liquid crystal display (LCD) monitor for displaying information to a user, a keyboard, and a pointing device such as a mouse or a trackball by which the user can provide input to apparatus 300.

Any or all of the functions of the systems and apparatuses discussed herein may be performed by processor 310, and/or incorporated in, an apparatus or a system such as system 100. Further, system 100 and/or apparatus 300 may utilize one or more neural networks or other deep-learning techniques performed by processor 310 or other systems or apparatuses discussed herein.

One skilled in the art will recognize that an implementation of an actual computer or computer system may have other structures and may contain other components as well, and that FIG. 3 is a high-level representation of some of the components of such a computer for illustrative purposes.

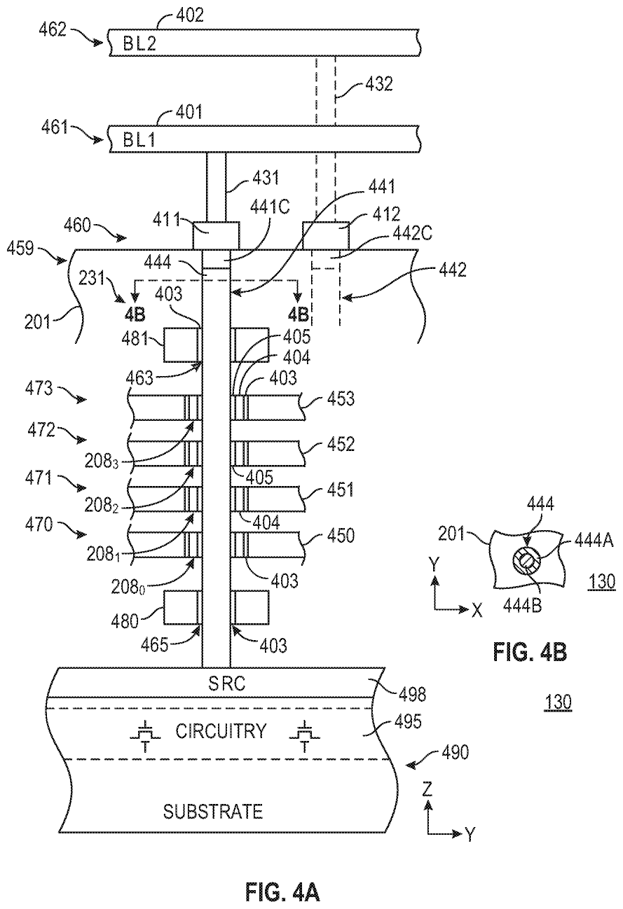

FIG. 4A shows a side view (e.g., a cross section with respect to the X-Z directions) of a portion of the three-dimensional structure of memory device 130 including a structure of memory cell string 231 (e.g., a NAND string) having a pillar 441, according to some embodiments described herein. FIG. 4A shows the structure of one memory cell string (e.g., memory cell string 231) of memory device 130. However, other memory cell strings (e.g., NAND strings 2060-206M in FIG. 2A and NAND strings 206 in FIG. 2B) can have a similar or the same structure as memory cell string 231 shown in FIG. 4A.

Starting from the top of FIG. 4A, memory device 130 have data lines 401 and 402 (e.g., corresponding to bit lines 204 in FIGS. 2A, 2B, and 2C) coupled to conductive structures 431 and 432, respectively, and coupled to conductive contacts 411 and 412, respectively. Data lines 401 and 402 are therefore electrically connected to pillars 441 and 442, respectively, via the conductive contacts 411 and 412, respectively. It is understood that memory device 130 can include many other similar data lines, conductive structures, and conductive contacts, which are not shown for simplicity.

FIG. 4A shows directions X, Y, and Z that can be relative to the physical directions (e.g., dimensions) of the structure of memory device 130. For example, the Z-direction can be a direction perpendicular to (e.g., vertical direction relative to) a substrate (e.g., a semiconductor substrate) of memory device 130. The Z-direction is perpendicular to the X-direction and Y-direction (e.g., the Z-direction is perpendicular to an X-Y plane of memory device 130).

As shown in FIG. 4A, data lines 401 and 402 can carry signals (e.g., bit line signals) BL1 and BL2, respectively. In the physical structure of memory device 130, data lines 401 and 402 can be structured as conductive lines and have respective lengths extending in the Y-direction. The data lines (e.g., data lines 401 and 402) of memory device 130 can be formed on different levels (e.g., layers) in the physical structure of memory device 130. For example, data lines 401 can be formed on one level (e.g., a lower level 461) of memory device 130, and data lines 402 can be formed on another level (e.g., an upper level 462) of memory device 130. Although not shown in FIG. 4A, multiple data lines can be located side-by-side in any particular level. For example, level 461 may have multiple data lines and level 462 may also have multiple data lines. Data lines in the same level can be separated from each other by a distance (e.g., a gap) in the X-direction. The gaps between data lines in the same level may be the same or different. As shown in FIG. 4A, each of data lines 401 and 402 can have a thickness in the Z-direction and a width in the X-direction. Each of the thickness (in the Z-direction) and the width (in the X-direction) is less than the length (in the Y-direction). The thickness can be less than, equal to, or greater than the width.

In FIG. 4A, each of conductive structures 431 and 432 can have a length extending in the Z-direction. In some examples, the length of conductive structure 431 can be less than the length of conductive structure 432, because level 461 is a lower level that is located closer to memory array 201. Each of conductive structures 431-432 can include (e.g., can be formed from) a conductive material that extends in the Z-direction. Examples of the conductive material include metal, alloy, conductively doped polysilicon, or other conductive materials. Although not shown in FIG. 4A, memory device 130 can include a dielectric material (e.g., silicon dioxide) formed between levels 462 and 461. The dielectric material can be formed before conductive structures 431 and 432. Then, openings (e.g., holes (e.g., vertical vias)) can be formed in the dielectric material. The material of each of conductive structures 431-432 can be formed (e.g., deposited) inside a respective opening of the openings.

As shown in FIG. 4A, each of conductive structures 431 and 432 can be coupled to (e.g., in electrical contact with) a respective conductive contact among conductive contacts 411 and 412 and coupled to (e.g., in electrical contact with) a respective data line among data lines 401 and 402. For example, conductive structure 431 can include an end (e.g., bottom end) coupled to (e.g., directly contacting) conductive contact 411, and another end (e.g., top end) coupled to (e.g., directly contacting) data line 401. In another example, conductive structure 432 can include an end (e.g., bottom end) coupled to (e.g., directly contacting) conductive contact 412, and another end (e.g., top end) coupled to (e.g., directly contacting) data line 402.

As shown in FIG. 4A, memory cell string 231 can include pillars (e.g., vertical pillars) 441 and 442. Pillars 441 and 442 can include pillar contacts 441C and 442C, respectively, located on the same level (e.g., level 459) of memory device 130. Pillars 441 and 442 can be located under (e.g., directly under) respective conductive contacts 411 and 412, which are under (e.g., directly under) respective conductive structures 431 and 432. Conductive structures 431 and 432 can be coupled to (e.g., in electrical contact with) pillars 441 and 442, respectively, through conductive contacts 411 and 412, respectively. Thus, as shown in FIG. 4A, data lines 401 and 402 can be coupled to (e.g., electrically coupled to) pillars 441 and 442, respectively, through respective conductive structures 431 and 432 and respective conductive contacts 411 and 412.

As described above, data lines 401 and 402 are located in levels 461 and 462, respectively. Levels 461 and 462 are in portion of memory device 130 that is located above memory array 201 in the Z-direction. Memory array 201 is located above a substrate 490 of memory device 130 in the Z-direction. As described above, a memory array such as memory array 201 includes multiple memory cell strings (one of which is shown as memory cell string 231).

As shown in FIG. 4A, pillar (e.g., a vertical pillar) 441 can be a part of memory cell string 231 and can have a length extending in the Z-direction (e.g., extend vertically with respect to substrate 490). Pillar 441 can extend through memory cells 2080, 2081, 2082, and 2083 of memory cell string 231. Pillar 441 can include (e.g., can be formed from) a conductive material (e.g., conductively doped polysilicon). Each of memory cells 2080, 2081, 2082, and 2083 can include a structure of transistor (e.g., a memory cell transistor). Part of pillar 441 can form the channel region (e.g., to conduct current) of the transistor of each memory cells 208₀, 208₁, 208₂, and 208₃. It is understood that while FIG. 4A only shows four memory cells 208₀-208₃, memory cell string 231 can include any number of memory cells that share a same pillar (e.g., pillar 441).

As described above, pillar contact 441C can be formed from conductively doped polysilicon, metal, or other conductive materials. Pillar 441 can include a portion 444. Pillar contact 441C and portion 444 of pillar 441 can include the same conductive material or different conductive materials. Conductive structure 431, conductive contact 411, and pillar 441 can be part of a circuit path (e.g., a conductive channel of memory cell string 231) between data line 401 and a conductive region 498 (associated with an SRC line). Conductive region 498 can be a part of a common source line (e.g., common source line or source plate 216 in FIG. 2A). Conductive structure 431 and pillar 441 can have the same material or different materials. In FIG. 4A, during a memory operation (e.g., read or write operation) of memory device 130, a circuit path (e.g., a current path) can be formed between data line 401 and conductive region 498 through conductive structure 431, conductive contact 411, and pillar 441 (which includes pillar contact 441C and portion 444 of pillar 441).

Substrate 490 of memory device 130 can include a semiconductor substrate (e.g., silicon-based substrate). For example, substrate 490 can include a p-type silicon substrate or an n-type silicon substrate. As shown in FIG. 4A, memory cells 208₀, 208₁, 208₂, and 208₃ of memory cell string 231 can be located along (e.g., adjacent) respective portions of pillar 441 in different levels (in the Z-direction) of memory device 130. For example, memory cells 208₀, 208₁, 208₂, and 208₃ can be located one over another (e.g., formed vertically) in levels 470, 471, 472, and 473, respectively, of memory device 130. Memory cells of other memory cell strings of memory device 130 can also be located on respective levels 470, 471, 472, and 473.

By stacking the memory cells in different levels, the memory device forms a 3D structure that has a higher capacity than a 2D device. In a typical 3D memory device (e.g., device 130 shown in FIG. 4A), for example, multiple levels (e.g., levels 470, 471, 472, and 473) are stacked together with one or more memory pillars (e.g., pillars 441 and 442) disposed vertically in the middle. The memory pillars may act as the channel region of the memory device. The multiple levels (e.g., layers or tiers) of the memory device may form groups or decks. A deck of a 3D memory device may be processed together (e.g., patterned and/or etched together) when forming the memory pillar associated thereof. A level of the memory device may have one or more access lines (e.g., word lines) or access line groups (e.g., word line groups). Each deck may have one or more access line segments (e.g., word line segments). An access line segment may have fewer or more access lines than those in a deck. For example, a deck may have two word line segments distributed in one or more levels. In some cases, certain memory operations (e.g., an erase operation) can be performed to a word line group (e.g., a deck), and not to the entire memory block. By not performing an operation to the entire memory block, the particular operation may be performed faster.

FIG. 4A further illustrates that access lines 450, 451, 452, and 453 of memory device 130 can be located along (e.g., adjacent) respective portions (in the Z-direction) of pillar 441 in the same levels (e.g., levels 470, 471, 472, and 473, respectively) that memory cells 208₀, 208₁, 208₂, and 208₃ are located. Access lines can include, for examples, word lines or control gates. Access lines 450, 451, 452, and 453 can include (e.g., can be formed from) a conductive material (or materials). Example materials for access lines 450, 451, 452, and 453 include metal, alloy, doped polysilicon, other conductive materials.

In FIG. 4A, a select line (e.g., drain select gate or SGD) 481 can have a length extending in the X-direction (e.g., perpendicular to the lengths (in the Y-direction) of data lines 401 and 402). The materials of select line 481 can include a conductive material (e.g., conductively doped polysilicon, metal, other conductive material). FIG. 4A shows an example where another select line (e.g., source select gate or SGS) 480 can have a structure (e.g., shape, material, or both) similar to (or the same as) that of select line 481. In some examples, select line 480 can have a structure (e.g., shape, material, or both) similar to (or the same as) that of each of access lines 450, 451, 452, and 453.

As shown in FIG. 4A, a transistor (e.g., source select transistor) 465 and a transistor (e.g., drain select transistor) 463 can be located along (e.g., adjacent) respective portions of pillar 441 in the Z-direction. Memory cells 208₀, 208₁, 208₂, and 208₃ of memory cell string 231 can be located along the portion of pillar 441 that is between transistors 465 and 463.

Memory cell string 231 can include materials 403, 404, and 405 formed between portion 444 of pillar 441 and a respective access line among access lines 450, 451, 452, and 453. Material 403 can also be formed between pillar 441 and each of select lines 480 and 481. Materials 403, 404, and 405 located at a particular memory cell (among memory cells 208₀, 208₁, 208₂, and 208₃) can be a part (e.g., a memory element) of that particular memory cell. As shown in FIG. 4A, the combination of materials 403, 404, and 405 of a memory cell (among memory cells 208₀, 208₁, 208₂, and 208₃) can be separated from (in the Z-direction) the combination of materials 403, 404, and 405 of another memory cell (among memory cells 208₀, 208₁, 208₂, and 208₃).

Material 403 can include a charge blocking material (or charge blocking materials), for example, a dielectric material (e.g., silicon nitride) that is capable of blocking a tunneling of a charge. Material 404 can include a charge storage material (or charge storage materials) that can provide a charge storage function to represent a value of information stored in memory cells 208₀, 208₁, 208₂, and 208₃. For example, material 404 can include polysilicon (e.g., conductively doped polysilicon), which can be either a p-type polysilicon or an n-type polysilicon. The polysilicon can be configured to operate as a charge trap (e.g., to store charge) in a memory cell (e.g., a memory cell 208₀, 208₁, 208₂, and 208₃). In another example, material 404 can include a dielectric material (e.g., silicon-nitride based material or other dielectric materials) that can trap charge in a memory cell (e.g., a memory cell 208₀, 208₁, 208₂, and 208₃). Material 405 can include a tunnel dielectric material (or tunnel dielectric materials), for example, silicon dioxide, that is capable of allowing tunneling of a charge (e.g., electrons).

As shown in FIG. 4A, memory device 130 can include circuitry 495 located (e.g., formed) under memory array 201 (e.g., located directly under memory cell string 231). Circuitry 495 can include circuit elements (e.g., transistors T) coupled to other circuit elements (e.g., coupled to data lines 401-402) of memory device 130. The circuit elements (e.g., transistors T) of circuitry 495 can be configured to perform part of a function of a memory device (e.g., memory device 130). For example, circuitry 495 can include decoder circuits, driver circuits, buffers (e.g., page buffers), sense amplifiers, charge pumps, and other circuitry of memory device 130. In an alternative structure of memory device 130, circuitry 495 can be located (e.g., formed) above memory array 201 (instead of under memory array 201). For example, in the alternative structure of memory device 130, circuitry 495 can be located above memory array 201 and under data lines 401 and 402, or located between data lines 401 and 402 of memory array 201 in the Z-direction. In another example, in the alternative structure of memory device 130, circuitry 495 can be located above memory array 201 and above data lines 401 and 402 in the Z-direction.

A different view of pillar 441 along a cross-sectional line 4B-4B is shown in FIG. 4B. FIG. 4B shows a top view (e.g., a cross section with respect to the X-Y plan) of portion 444 of pillar 441 along line 4B-4B of FIG. 4A. As shown in FIG. 4B, portion 444 of pillar 441 can include material 444A and material 444B surrounded by material 444A. Material 444A can be (or can include) a part of a conductive structure (e.g., a conductive channel) of pillar 441. Material 444B can include a dielectric material. In an alternative structure of pillar 441, material 444B can be omitted from pillar 441, such that the entire portion 444 of pillar 441 can include material 444A (without material 444B).

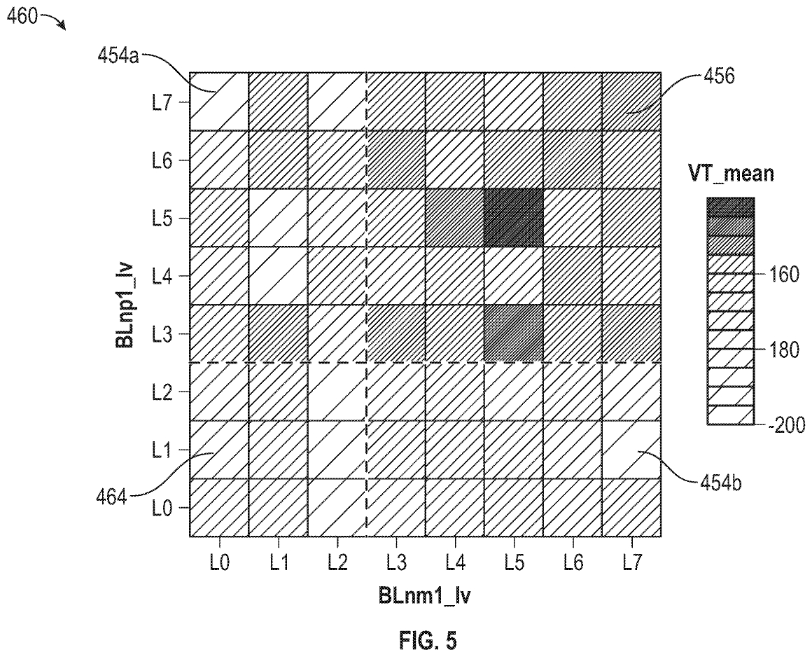

As discussed above, capacitive coupling and/or cross talk between the bit lines 204 can create BL-BL interference when the memory device 130 performs read operations. FIG. 5 illustrates a graphical representation 460 of an example heat map of read values obtained as part of a read operation performed on a page of memory cells. In this example heat map, the read values were obtained using a first strobe of an upper page of memory cells and shows an impact that BL-BL interference can have on Vt values.

In the graphical representation 460, the vertical or Y axis represents expected read levels of a neighboring bit line in a positive direction (e.g., BL n+1) and the horizontal or X axis represents expected read levels of a neighboring bit line in a negative direction (e.g., BL n−1). The neighboring bit lines may include bit lines that are close in proximity to each other (e.g., the bit lines 204₀ and 204₁ and the bit lines 204₁ and 204₂ of FIGS. 2A-2D) (e.g., adjacent bit lines).

In FIG. 5, the shade or pattern within each square represents an average Vt value as a function of expected read levels in the neighboring bit lines. As shown in FIG. 5, as the expected read levels of the neighboring bit lines increase, the average Vt value increases (indicated by darker shading/different patterns in FIG. 5), indicating that aggression due to BL-BL interference increases as the expected read values of the neighboring memory cells increase. Accordingly, the aggression of the neighboring bit lines can be divided for this example into four regions 464, 454a-b, and 456 that correspond to various levels of aggression. The four regions 464, 454a-b, and 456 correspond to three separate “bins” or “levels” of aggression.

The first region 464 corresponds to the memory cells that experienced no aggression due to the neighboring bit lines (e.g., squares representing an average Vt value of around negative one hundred eighty-nine millivolts (mV)). In more detail, the first region 464 corresponds to the memory cells in which both neighboring bit lines are coupled to memory cells that have a Vt value that is less than a voltage level applied to the corresponding word lines. For example, the first region 464 corresponds to memory cells that were exposed to a first level of aggression.

The two instances of the second region 454a-b correspond to the memory cells that experienced low aggression due to the bit lines coupled to the neighboring memory cells (e.g., squares representing an average Vt value of around negative one hundred seventy-four mV). In more detail, the two instances of the second region correspond to the memory cells in which one of the neighboring bit lines is coupled to a memory cell that has a Vt value that that is greater than the voltage level applied to the corresponding word line and one of the neighboring bit lines is coupled to a memory cell that has a Vt value that that is less than the voltage level applied to the corresponding word line. For example, the second regions 454a-b correspond to the memory cells that were exposed to a second level of aggression.

The third region 456 corresponds to the memory cells that experienced high aggression due to the neighboring bit lines (e.g., squares representing an average Vt value of around negative one hundred fifty-six mV). In more detail, the third region 456 corresponds to the memory cells in which both neighboring bit lines are coupled to memory cells that have a Vt value that is greater than the voltage level applied to the corresponding word lines. For example, the third region 456 corresponds to the memory cells that were exposed to a third level of aggression.

The three levels of aggression (e.g., regions 464, 454a-b, and 456) are discussed in relation to FIG. 5 and throughout the present disclosure merely as examples. It is understood that the levels of aggression may include any appropriate number of levels. For example, the levels of aggression may include two, four, five, or more levels. Additionally or alternatively, the levels of aggression may include sub-levels. For example, the second level of aggression may include two, three, or more sub-levels.

With reference back to FIGS. 1-4B, to address the technical challenges described above, in some embodiments of the present technology, control logic of the memory device 130 may initiate a read operation including a sense phase of a page of the memory cells 208. The terms “control logic,” “local controller” (e.g., the local controller 135), and “system controller” (e.g., the system controller 115) may be used interchangeably in the present disclosure. In some examples, the control logic includes the local controller 135 or the system controller 115. In other example, the control logic includes any combination of the local controller 135, the system controller 115, the page buffer 152, the sense amplifier 245, the row decoder 108, or the column decoder 111. Operations described in the present disclosure as being performed by the local controller 135 (e.g., a memory controller), may alternatively be performed by the system controller 115 and vice versa.

After the sensing phase, the page buffer 152 senses the voltage level of each corresponding sense node within the sense circuits 243₀-243_{M} at different points in time. For each of the different points in time, the local controller 135 or the page buffer 152 may cause a bias voltage corresponding to a page of memory cells 208 to be adjusted to obtain multiple read values. For example, the local controller 135 may cause a word line bias voltage, a bit line bias voltage, or both to be adjusted to obtain multiple read values. As another example, the local controller 135 may cause a current on the bit lines 204 to be regulated to obtain multiple read values. As yet another example, the page buffer 152 may cause the boost voltage to be adjusted to obtain multiple read values.

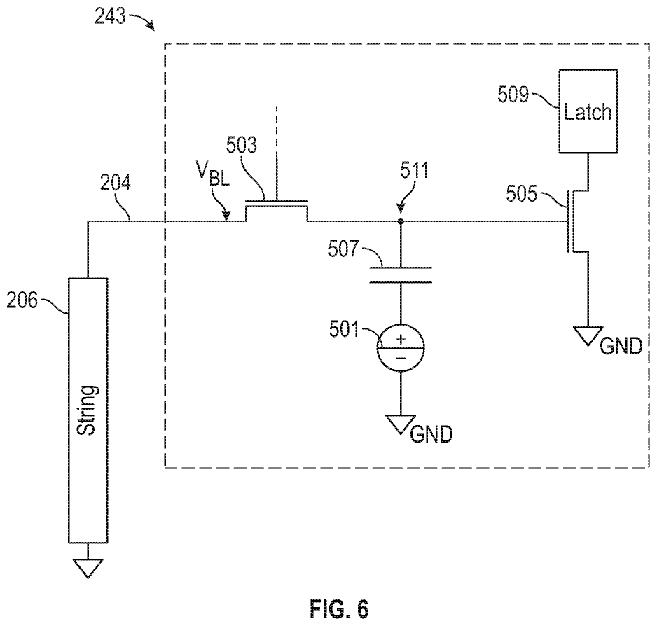

FIG. 6 illustrates an example sense circuit 243 and a string of memory cells 206. The sense circuit 243 may correspond to any of the sense circuits 243₀-243_{M} of FIG. 2C. As shown in FIG. 6, the sense circuit 243 includes a clamp transistor 503, a sense transistor 505, a boost voltage source 501, a capacitor 507, and a latch 509. In some embodiments, the node 511 may also be called the sense node. In some examples, the memory controller activates (e.g., turn on) clamp transistor 503 to sense the current flowing through bit line 204 (and string 206). The capacitor 507 integrates the current and converts the current signal to a voltage at sense node 511. The sense transistor 505 receives the voltage at sense node 511 and may turn on if the voltage is greater than the threshold voltage of the sense transistor 505. Therefore, depending on the current flowing through bit line 204, the voltage of node 511 may be low or high. The boost voltage source 501 may apply a variable boost voltage to the sense node 511 via the capacitor 507 to adjust a level of the voltage at the sense node 511. The sense transistor 505 may be activated (e.g., turned on if the voltage at node 511 is high) or remain inactivated (e.g., turned off). In the example shown in FIG. 6, if the sense transistor 505 is turned on, the latch 509 may store a low value (e.g., because the transistor 505 pulls down the voltage at the input to latch 509 to the ground). Otherwise, the latch 509 may keep the currently-stored value. Thus, the sense transistor 505 controls the data stored in the latch 509, depending on the sensed voltage level during the sense phase or different points time. In addition, as described above, the clamp transistor 503, being controlled by the memory controller, can selectively connect the string of memory cells 206 to the node 511.

Modifications or additions may be made to the example sense circuit 243 and the string of memory cells 206 shown in FIG. 6. The example sense circuit 243 and the string of memory cells 206 may include more or fewer elements than those illustrated and described in the present disclosure. For example, the example sense circuit may include additional transistors to maintain the voltage on the bit line 204. As another example, the example sense circuit 243 may include additional transistors to further decouple the bit line 204 from the node 511.

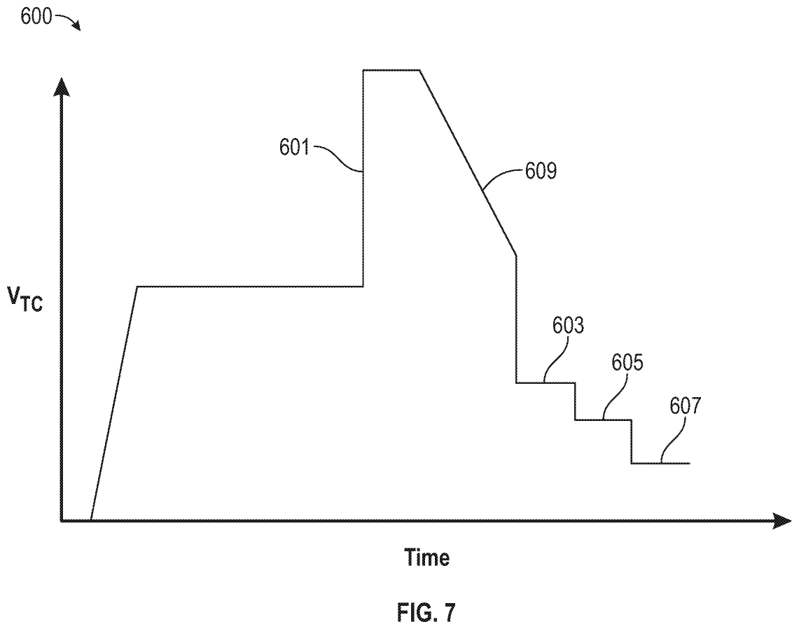

FIG. 7 illustrates a graphical representation 600 of voltage measured on an example sense node (e.g., sense node 511 of FIG. 6), the representation of which can be stored in latch 509. The horizontal axis of FIG. 7 represents time, and the vertical axis of FIG. 7 represents the voltage measured on the sense node 511 (also referred to as the voltage of the temporary cache or VTC). Curve 601 represents the voltage measured on the sense node 511 during a three-boost modulation read operation. Portion 609 of the curve 601 (e.g., a down slope portion of the curve 601) corresponds to the sense phase. In addition, portions 603, 605, and 607 correspond to the different points in time after the sense phase for which different levels of boost are applied to the sense node. For instance, at the first point in time, a boost voltage of zero volts may be applied; at the second point in time, a boost voltage of negative twenty mV may be applied; and at the third point in time, a boost voltage of negative forty mV may be applied. As described above, the boost voltage can be provided by a boost voltage source 501.

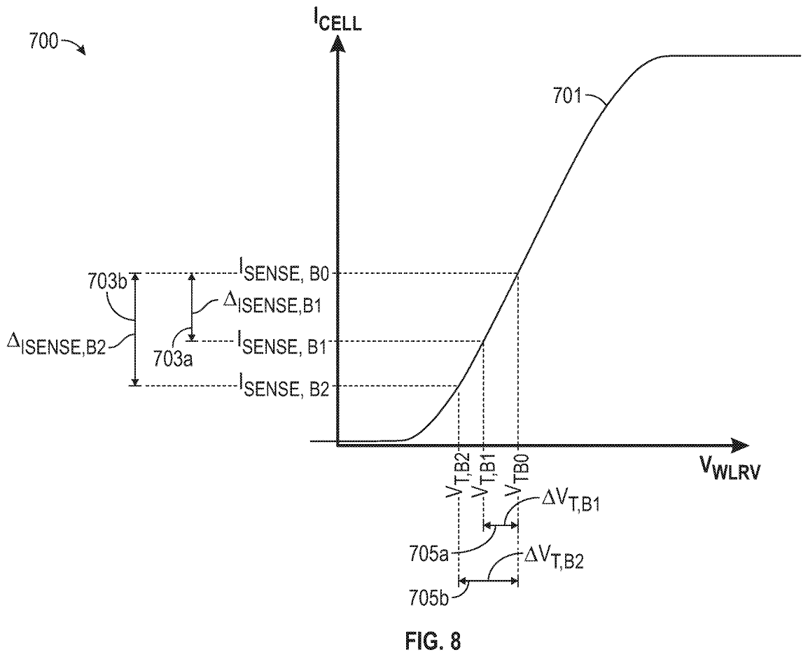

FIG. 8 illustrates a graphical representation 700 of an example IV curve 701. The example IV curve 701 shows correlations between changes in a current in a bit line and a voltage on the word line to determine the voltage level of the boost voltage to use at the different points in time. In FIG. 8, the vertical or Y axis represents current on the corresponding memory cell and the horizontal or X axis represents voltage on the corresponding word line. The IV curve 701 indicates the voltage levels of the boost voltage that correspond to different levels of current on the memory cell during the sense phase. Additionally, the IV curve 701 indicates how much the boost voltage should be changed to represent different amounts of increases in the current on the memory cell during the sense phase.

The IV curve 701 indicates how to convert between changes in current on the sense node and changes in voltage on the sense node. In FIG. 8, a change in the current on the sense node between a first point in time and a second point in time is represented by arrow 703a and a change in the current on the sense node between the first point in time and a third point in time is represented by arrow 703b.

Accordingly, to represent these changes as voltage on the sense node, the current is converted to volts to determine the voltage levels. In FIG. 8, the change in the current between the first point in time and the second point in time is represented by arrow 705a and the change in the current between the first point in time and the third point in time is represented by arrow 705b.

With reference to FIGS. 1-7, the boost voltage level that is applied at the different points in time may decrease the voltage level of the curve 601 (e.g., the boost voltage may include a negative voltage level) in different sized steps to represent what changes in voltage would be detected if an increase in the current on the string of memory cells 206 occurred during the sense phase. As shown in FIG. 7, the first point in time (e.g., portion 603), the second point in time (e.g., portion 605), and the third point in time (e.g., portion 607) occur after the sense phase (e.g., portion 609).

During the sense phase, the clamp transistor 503 may be closed (e.g., turned on) to connect the string of memory cells 206 to the node 511 and cause a voltage stored on the capacitor 507 to be discharged by current on the string of memory cells 206. In addition, the sense transistor 505 may be closed to connect the latch 509 to the node 511 and the string of memory cells 206 (e.g., the sense node to the string of memory cells 206). The current on the string of memory cells 206 and the voltage stored on the capacitor 507 during the sense phase causes the voltage level on the sense node 511 (e.g., portion 609) to decrease. Accordingly, parameters of the capacitor 507 may define an amount of current on the string of memory cells 206 that is to be used to determine to which of the supported states a corresponding memory cell of the string of memory cells 206 is programmed to.

After the sense phase, the voltage level of the sense node 511 can be sampled on the latch 509 through the sense transistor 505. In some embodiments, timing of the sampling of the voltage level of the sense node 511 is based on circuitry internal to the latch 509. At the time of the sampling, if the voltage level of the sense node 511 is equal to or greater than the Vt of the sense transistor 505 (e.g., the corresponding transistor), the latch 509 may store a logical 0. Alternatively, at the time of the sampling, if the voltage level of the sense node 511 is less than a Vt of the sense transistor 505, the latch 509 may store a logical 1. Details of these operations are described in more detail below.

After the sense phase, the clamp transistor 503 opens (e.g., turned off) to electrically isolate the string of memory cells 206 from the sense node 511 (e.g., the string of memory cells 206 are electrically isolated from the capacitor 507, the boost voltage source 501, the sense transistor 505, or the latch 509) at the different points in time. In addition, after the sense phase, the sense transistor 505 may close to connect the latch 509 to the sense node 511 (e.g. connected to the capacitor 507 or the boost voltage source 501) at the different points in time. In some embodiments, the sense transistor 505 closes if the voltage level on the sense node 511 is equal to or greater than the Vt of the sense transistor 505.

At the first point in time, the page buffer 152 may cause the boost voltage source 501 to apply the boost voltage at a first level and cause the voltage level on the sense node 511 (e.g., the first portion 603) to decrease from the voltage level during the sense phase. The page buffer 152 compares the voltage level of the sense node 511 at the first point in time to a corresponding Vt value (e.g., the Vt value of the sense transistor 505) to determine a first read value of the corresponding memory cell of the string of memory cells 206.

At the second point in time, the page buffer 152 may cause the boost voltage source 501 to apply the boost voltage at a second level and cause the voltage level on the sense node 511 (e.g., the second portion 605) to further decrease from the voltage during the sense phase. The page buffer 152 compares the voltage level of the sense node 511 at the second point in time to the corresponding Vt value (e.g., the Vt value of the sense transistor 505) to determine a second read value of the corresponding memory cell of the string of memory cells 206.

At the third point in time, the page buffer 152 may cause the boost voltage source 501 to apply the boost voltage at a third level and cause the voltage level on the latch sense node 511 (e.g., the third portion 607) to further decrease from the voltage level during the sense phase. The page buffer 152 compares the voltage level of the sense node 511 at the third point in time to the corresponding Vt value (e.g., the Vt value of the sense transistor 505) to determine a third read value of the corresponding memory cell of the string of memory cells 206.

With reference to FIGS. 1-4B, the page buffer 152 stores the read value for each of the memory cells of the page of memory cells based on the voltage level of the corresponding sense node at the corresponding points in time. The page buffer 152 sets and stores the different read values as a logical 1 if the voltage level of the associated sense node (e.g., latch 509 of FIG. 6) at the corresponding point in time is less than the corresponding Vt value. In these and other embodiments, the page buffer 152 sets and stores the different read value as a logical 0 if the voltage level of the associated sense node (e.g., latch 509 of FIG. 6) at the corresponding point in time is equal to or greater than the corresponding Vt value.

In some embodiments, the local controller 135 causes the column decoder 111 to adjust the bit line voltage, the row decoder 108 to adjust the word line voltage, or both at different points in time to cause the voltage level of the sense node 511 to change. The page buffer 152 may compare the voltage level of the sense node 511 to the corresponding Vt value to obtain the different read values.

Accordingly, the page buffer 152 may obtain multiple rounds of read values for the page of memory cells. Each read value of the rounds corresponds to a different memory cell of the page of memory cells. For example, each of the first read values corresponds to a different memory cell, each of the second read values corresponds to a different memory cell; and each of the third read values corresponds to a different memory cell. Therefore, the page buffer 152 generates, or the local controller 135 may receive, forty-eight kilobytes of data for a single sense phase of the page of memory cells rather than just sixteen kilobytes.

The local controller 135 may receive the read values from the page buffer 152. For example, the local controller 135 may receive the first read values, the second read values, or the third read values for the page of memory cells.

Example read values for seven memory cells (labelled MC0-MC6) that correspond to three different points in time that may be received by the local controller 135 are listed in Table 1. The read values in Table 1 are example read values that were determined using three-boost modulation.

TABLE 1

| | MC0 | MC1 | MC2 | MC3 | MC4 | MC5 | MC6 |
|---|---|---|---|---|---|---|---|
| 1^{st} Point | 1 | 0 | 1 | 0 | 0 | 0 | 0 |
| in Time | | | | | | | |
| 2^{nd} Point | 1 | 1 | 1 | 0 | 0 | 0 | 0 |
| in Time | | | | | | | |
| 3^{rd} Point | 1 | 1 | 1 | 1 | 0 | 1 | 0 |
| in Time | | | | | | | |

The local controller 135 selects a reference set of the read values (referred to herein as reference read values) to identify changed memory cells of the page of memory cells. The local controller 135 may select the first read values (e.g., the read values corresponding to the first point in time), the second read values (e.g., the read values corresponding to the second point in time), the third read values (e.g., the read values corresponding to the third point in time), or any combination or set of read values as the reference read values.

The local controller 135 identifies changed memory cells, which include the memory cells for which the corresponding read values are different at different points in time, based on the reference read values. In particular, the local controller 135 compares non-reference read values for each of the memory cells to the corresponding reference read value to determine if a change occurred. In other words, the local controller 135 may identify memory cells for which at least one corresponding read value is different than the corresponding reference read value. For example, using the first read values in Table 1 as the reference read values, the local controller 135 would identify the second memory cell (labeled as MC1 in Table 1), a fourth memory cell (labelled MC3 in Table 1), and a sixth memory cell (labelled MC5 in Table 1) as changed memory cells because their first read values are logical 0s and then either their second read values and/or the third read values are logical 1s. Specifically, in Table 1, for MC1, the read value changes from logical 0 to logical 1 from the first point of time to the second point of time. For MC3 and MC5, the read values both change from logical 0 to logical 1 from the second point of time to the third point of time. Each of these memory cells (MC0-MC6) is connected to a bit line, and therefore, they may also be referred to as BL0-BL6.

The local controller 135 determines levels of aggression for the bit lines coupled to the changed memory cells based on read values corresponding to the memory cells coupled to the neighboring bit lines. In some embodiments, the local controller 135 determines the levels of aggression for the bit lines coupled to the changed memory cells based on the first read values, the second read values, or the third read values of the memory cells coupled to the neighboring bit lines.

The local controller 135 can determine the levels of aggression in accordance with a pre-determined bin profile. In some embodiments, the pre-determined bin profile is programmed into the local controller 135 or provided by the system controller 115. In these and other embodiments, the pre-determined bin profile may identify the different levels of aggression, settings for the different levels of aggression, or both. For example, the pre-determined bin profile may identify the first level of aggression (e.g., a low level of aggression) that corresponds to when both of the first read values of the memory cells coupled to the neighboring bit lines are logical 1s; the second level of aggression (e.g., an intermediate level of aggression) that corresponds to when the first read value of one of the memory cells coupled to the neighboring bit lines is a logical 1 and the first read value of another of the memory cells coupled to the neighboring bit lines is a logical 0; and the third level of aggression (e.g., a high level of aggression) that corresponds to when both of the first read values of the memory cells coupled to the neighboring bit lines are logical 0s.

For example, using the first read values in Table 1, the local controller 135 would determine the level of aggression for the bit line coupled to the second memory cell (e.g., MC1) is the first level of aggression because the first read values for the first memory cell (e.g., MC0) and a third memory cell (labelled MC2 in Table 1) are logical 1s. As another example, the local controller 135 would determine the level of aggression for the bit line coupled to the fourth memory cell (e.g., MC3) as a second level of aggression because the first read value for the third memory cell (e.g., MC2) is a logical 1 and the first read value for a fifth memory cell (labelled MC4 in Table 1) is a logical 0. As yet another example, the local controller 135 would determine the level of aggression for the bit line coupled to a sixth memory cell (labelled MC5 in Table 1) as a third level of aggression because the first read values for the fifth memory cell (e.g., MC4) and a seventh memory cell (labelled MC6 in Table 1) are both logical 0s.

In some embodiments, the local controller 135 may disregard end memory cells (e.g., the first memory cell and the seventh memory cell or last memory cell) when identifying the changed memory cells. The local controller 135 may disregard the end memory cells because there is only one read value of a memory cell coupled to a neighboring bit line that may be used to determine the levels of aggression. Alternatively, the local controller 135 may use dummy bit line read values for determining the levels of aggression for the bit lines coupled to the end memory cells. In some embodiments, the dummy bit line read values may be permanently set to logical 0s or logical 1s. For example, the dummy bit line read values may be set to logical 1s to mimic or simulate less aggression for the bit lines coupled to the end memory cells. As another example, the dummy bit line read values may be set to logical 0s to mimic or simulate increased aggression for the bit lines coupled to the end memory cells.

The local controller 135 selects actual read values for the changed memory cells (e.g., read values expected to correspond to the actual supported state to which the changed memory cells are programmed to) from the stored read values based on the corresponding levels of aggression, the pre-determined bin profile, or both. The corresponding levels of aggression may indicate which of the corresponding read values the local controller 135 is to select as the actual read values. For instance, the local controller 135 may select the first read values for the changed memory cells corresponding to the first level of aggression. For example, referring to Table 1, the local controller 135 may select the first read value (e.g., logical 0) for the second memory cell (e.g., MC1). Alternatively, the local controller 135 may select the second read values for the changed memory cells corresponding to the second level of aggression. For example, referring to Table 1, the local controller 135 may select the second read value (e.g., logical 0) for the fourth memory cell (e.g., MC3). Further, the local controller 135 may select the third read values for the changed memory cells corresponding to the third level of aggression. For example, referring to Table 1, the local controller 135 may select the third read value (e.g., logical 1) for the sixth memory cell (e.g., MC5).

The local controller 135 selecting the actual read values for the changed memory cells based on the level of aggression can improve an accuracy of the data that is read out during the read operation. In particular, the local controller 135 may reduce an amount of errors in the data that is read out during the read operation by accounting for the interference (e.g., BL-BL interference) within the memory device 130. For instance, by gathering multiple read values and selecting the actual read value based on the level of aggression (e.g., amount of interference), the local controller 135 selects the read value of logical 1 for the second memory cells (e.g., MC1). However, without performing the operations described in the present disclosure, the local controller 135 would not gather multiple read values for the second memory cell (e.g., MC1) and would select logical 0 despite the memory cell actually being programmed to logical 1.

Alternatively, if a target only value (TOV) program verify (PV) is to be performed, the local controller 135 may determine the levels of aggression based on data on the neighboring bit lines that are read on fly from the page of memory cells. The local controller 135 may compare a read value of a particular memory cell to already obtained read values of the memory cells coupled to the neighboring bit lines of the particular memory cell.

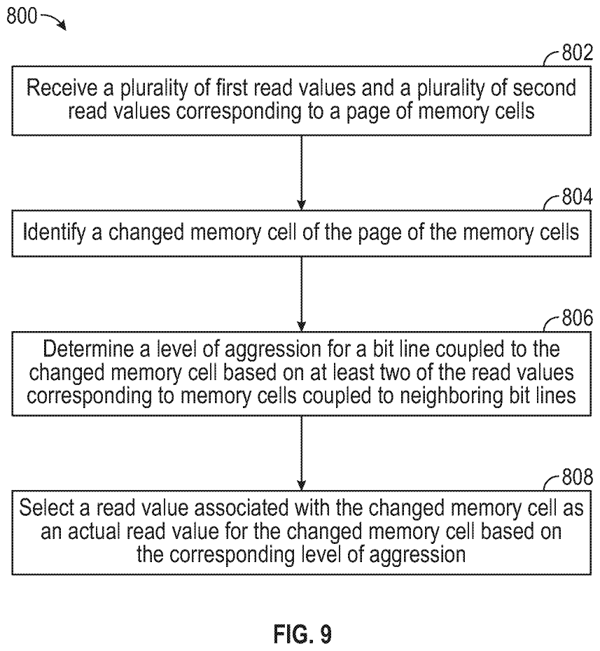

FIG. 9 illustrates a flowchart showing a method 800 that supports techniques for compensating for BL-BL interference in accordance with examples as disclosed herein. At least some of the blocks in method 800 can be performed by control logic (e.g., the local controller 135, the system controller 115, or the sense amplifier 245 of FIGS. 1 and 2) during a read operation or sense operation. At block 802, the control logic receives a plurality of first read values and a plurality of second read values corresponding to a page of the memory cells (e.g., a physical page of the memory cells 208). For example, the local controller 135 or the system controller 115 may receive the read values corresponding to a physical page of the memory cells 208.

In block 804, the control logic identifies a changed memory cell of the page of the memory cells. The controller may identify a memory cell for which a corresponding first read value is different than a corresponding second read value as the changed memory cell. For example, the local controller 135 or the system controller 115 may identify a memory cell of the physical page of the memory cells 208 for which the corresponding read values are different at different points in time.

In block 806, the control logic determines a level of aggression for a bit line coupled to the changed memory cell based on at least two of the read values corresponding to memory cells coupled to neighboring bit lines. For example, the local controller 135 or the system controller 115 may determine the level of aggression for the bit line coupled to the changed memory based on read values corresponding to memory cells coupled to neighboring bit lines. As another example, the local controller 135 or the system controller 115 may determine if the level aggression for the bit line coupled to the changed memory cell is the low level of aggression, the intermediate level of aggression, the high level of aggression, or any other appropriate level of aggression.

In block 808, the controller selects a read value associated with the changed memory cell as an actual read value for the changed memory cell based on the corresponding level of aggression. For example, the local controller 135 or the system controller may select the actual read value from stored read values based on the level of aggression.

Method 800 may include additional blocks not shown in FIG. 9. For example, the controller may sense a voltage level of a plurality of sense nodes at a first point in time and each of the sense nodes may correspond to a different memory cell. As another example, the controller may adjust a bias voltage corresponding to the page of the memory cells. As yet another example, the controller may sense a voltage level of the plurality of sense nodes at a second point in time that occurs after the bias voltage is adjusted. As an example, the controller may store the first read value for each of the memory cells based on the voltage level of the corresponding sense node at the first point in time and the controller may store the second read value for each of the memory cells based on the voltage level of the corresponding sense node at the second point in time.

It should be noted that the described techniques include possible implementations, and that the operations and the blocks may be rearranged, reordered, or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

A switching component or a transistor discussed herein may represent a field-effect transistor (FET) and include a three terminal device including a source, drain, and gate. The terminals may be connected to other electronic elements through conductive materials, e.g., metals. The source and drain may be conductive and may include a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processor, firmware, or any combination thereof. If implemented in software executed by a processor, the functions may be stored on or transmitted over, as one or more instructions or code, a computer-readable medium. Other examples and implementations are within the scope of the disclosure and appended claims. For example, due to the nature of software, the described functions can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device comprising:
memory cells;
control logic coupled to the memory cells and configured to:
receive a plurality of first read values and a plurality of second read values corresponding to a page of the memory cells;
identify a changed memory cell of the page of the memory cells, the changed memory cell comprising a memory cell for which a corresponding first read value is different than a corresponding second read value;
determine a level of aggression for a bit line coupled to the changed memory cell based on at least two of the read values corresponding to memory cells coupled to neighboring bit lines; and
select a read value associated with the changed memory cell as an actual read value for the changed memory cell based on the corresponding level of aggression.

2. The memory device of claim 1, wherein:
the page of memory cells is coupled to a plurality of bit lines; and
the memory device comprises a page buffer coupled to the plurality of bit lines, the page buffer comprising a plurality of sense nodes, each of the sense nodes corresponding to a different memory cell, the page buffer configured to
sense a voltage level of each of the sense nodes at a first point in time;
adjust a bias voltage corresponding to the page of the memory cells;
sense a voltage level of each of the sense nodes at a second point in time that occurs after the bias voltage is adjusted;
store the first read value for each of the memory cells based on the voltage level of the corresponding sense node at the first point in time; and
store the second read value for each of the memory cells based on the voltage level of the corresponding sense node at the second point in time.

3. The memory device of claim 2, wherein:
the page buffer is configured to compare the voltage level of each of the sense nodes at the first point in time to a voltage threshold (Vt) value of a corresponding transistor;
the first read value of a particular memory cell is set to 1 if the voltage level of the associated sense node at the first point in time is less than the corresponding Vt value; and
the first read value of the particular memory cell is set to 0 if the voltage level of the associated sense node at the first point in time is equal to or greater than the corresponding Vt value.

4. The memory device of claim 2, wherein changes to the voltage levels of the plurality of sense nodes occur due to at least one of:
changes to a word line voltage applied to the page of memory cells;
changes to corresponding bit line voltages applied to the page of memory cells;
changes to boost voltages applied to the plurality of sense nodes; or
changes to current on corresponding bit lines associated with the page of memory cells.

5. The memory device of claim 1, wherein:
the control logic is configured to receive a plurality of third read values corresponding to the page of memory cells; and
the changed memory cell comprises a memory cell for which the corresponding first read value is different than at least one of the corresponding second read value or the corresponding third read value.

6. The memory device of claim 5, wherein the control logic is configured to determine the level of aggression for the bit line coupled to the changed memory cell in accordance with a pre-determined bin profile that identifies:
a first level of aggression corresponding to when both of the first read values of the memory cells coupled to the neighboring bit lines are set to 1;
a second level of aggression corresponding to when the first read value of one of the memory cells coupled to the neighboring bit lines is set to 1 and of the first read value of another of the memory cells coupled to the neighboring bit lines is set to 0; and
a third level of aggression corresponding to when both of the first read values of the memory cells coupled to the neighboring bit lines are set to 0.

7. The memory device of claim 5, wherein the control logic is configured to determine the level of aggression for the bit line coupled to the changed memory cell based on at least one of:
the first read values of the memory cells coupled to the neighboring bit lines;
the second read values of the memory cells coupled to the neighboring bit lines; or
the third read values of the memory cells coupled to the neighboring bit lines.

8. A memory system comprising:
memory cells;
control logic configured to:
receive a plurality of first read values and a plurality of second read values corresponding to a page of the memory cells;
identify a changed memory cell of the page of memory cells, the changed memory cell comprising a memory cell for which a corresponding first read value is different than a corresponding second read value;
determine a level of aggression for a bit line coupled to the changed memory cell based on at least two of the read values corresponding to memory cells coupled to neighboring bit lines; and
select a read value associated with the changed memory cell as an actual read value for the changed memory cell based on the corresponding level of aggression.

9. The memory system of claim 8, wherein:
each of the first read values corresponds to a different memory cell; and
each of the second read values corresponds to a different memory cell.

10. The memory system of claim 8, wherein the memory system comprises a memory device comprising:
the page of memory cells coupled to a plurality of bit lines; and
a page buffer coupled to the plurality of bit lines and comprising a plurality of sense nodes, each of the sense nodes corresponding to a different memory cell, the page buffer configured to
sense a voltage level of each of the sense nodes at a first point in time;
adjust a bias voltage corresponding to the page of the memory cells;
sense a voltage level of each of the sense nodes at a second point in time that occurs after the bias voltage is adjusted;
store the first read value for each of the memory cells based on the voltage level of the corresponding sense node at the first point in time; and
store the second read value for each of the memory cells based on the voltage level of the corresponding sense node at the second point in time.

11. The memory system of claim 10, wherein changes to the voltage levels of the plurality of sense nodes occur due to at least one of:
changes to a word line voltage applied to the page of memory cells;
changes to corresponding bit line voltages applied to the page of memory cells;
changes to boost voltages applied to the plurality of sense nodes; or
changes to current on corresponding bit lines associated with the page of memory cells.

12. The memory system of claim 8, wherein the control logic is configured to determine the level of aggression for the bit line coupled to the changed memory cell in accordance with a pre-determined bin profile.

13. The memory system of claim 8, wherein:
the control logic is configured to receive a plurality of third read values corresponding to the page of memory cells; and
the changed memory cell comprises a memory cell for which the corresponding first read value is different than at least one of the corresponding second read value or the corresponding third read value.

14. The memory system of claim 13, wherein the control logic is configured to determine the level of aggression for the bit line coupled to the changed memory cell in accordance with a pre-determined bin profile that identifies:
a first level of aggression corresponding to when both of the first read values of the memory cells coupled to the neighboring bit lines are set to 1;
a second level of aggression corresponding to when the first read value of one of the memory cells coupled to the neighboring bit lines is set to 1 and of the first read value of another of the memory cells coupled to the neighboring bit lines is set to 0; and
a third level of aggression corresponding to when both of the first read values of the memory cells coupled to the neighboring bit lines are set to 0.

15. A method comprising:
receiving a plurality of first read values and a plurality of second read values corresponding to a page of memory cells;
identifying a changed memory cell of the page of the memory cells, the changed memory cell comprising a memory cell for which a corresponding first read value is different than a corresponding second read value;
determining a level of aggression for a bit line coupled to the changed memory cell based on at least two of the read values corresponding to memory cells coupled to neighboring bit lines; and
selecting a read value associated with the changed memory cell as an actual read value for the changed memory cell based on the corresponding level of aggression.

16. The method of claim 15, wherein:
each of the first read values corresponds to a different memory cell; and
each of the second read values corresponds to a different memory cell.

17. The method of claim 15 further comprising:
sensing a voltage level of a plurality of sense nodes at a first point in time, each of the sense nodes corresponding to a different memory cell;
adjusting a bias voltage corresponding to the page of the memory cells;
sensing a voltage level of the plurality of sense nodes at a second point in time that occurs after the bias voltage is adjusted;
storing the first read value for each of the memory cells based on the voltage level of the corresponding sense node at the first point in time; and
storing the second read value for each of the memory cells based on the voltage level of the corresponding sense node at the second point in time.

18. The method of claim 17, wherein:
the method further comprises comparing the voltage level of each of the sense nodes at the first point in time to a voltage threshold (Vt) value of a corresponding transistor;
setting the first read value of a particular memory cell to 1 if the voltage level of the associated sense node at the first point in time is less than the corresponding Vt value; and
setting the first read value of a particular memory cell to 0 if the voltage level of the associated sense node at the first point in time is equal to or greater than the corresponding Vt value.

19. The method of claim 15, wherein the level of aggression for the bit line coupled to the changed memory cell is determined in accordance with a pre-determined bin profile.

20. The method of claim 15, wherein:
the method further comprises receiving a plurality of third read values corresponding to the page of memory cells; and
the changed memory cell comprises a memory cell for which the corresponding first read value is different than at least one of the corresponding second read value or the corresponding third read value.
